(19) United States
(12) Patent Application Publication
(10) Pub. No.: US 2009/0104421 A1
(43) Pub. Date: Apr. 23, 2009

(54) PROCESS FOR MAKING A LAMINATE

(76) Inventors: Hubertus Marie Christine Stijnen, Stein (NL); Shahab S. Jahromi, Maastricht (NL)

Correspondence Address: NIXON & VANDERHYE, PC, 901 NORTH GLEBE ROAD, 11TH FLOOR, ARLINGTON, VA, 22203, US

(21) Appl. No.: 12/296,599

(22) PCT Filed: Apr. 3, 2007
(86) PCT No.: PCT/EP2007/002981

§ 371 Date: Dec. 30, 2008

(30) Foreign Application Priority Data
Apr. 13, 2006 (EP) 06007806.0

(51) Int. Cl. B32B 27/10; B32B 5/02; B32B 29/02; C23C 16/00; B32B 37/10

(52) U.S. Cl. 428/219; 428/537.5; 442/412; 428/323; 427/255.6; 156/60; 156/578

(57) ABSTRACT

The invention relates to a resin impregnated paper substrate with crystalline triazine, preferable vapor deposited triazine. The crystalline triazine preferably is present in an amount of about 5 g/m2 or higher and about 100 g/m² or lower. The invention further relates to a process for making a laminate comprising at least one cured layer of amine-formaldehyde resin and a paper, wherein a resin impregnated paper with vapor deposited triazine is submitted with one or more other layers to pressure and/or sufficient temperature to cure the resin and at least part of the triazine.

The invention relates to a process for making a laminate, in particular a decorative laminate. The laminate comprises at least one cured layer of preferably melamine-formaldehyde resin and paper, preferably paper with a color or pattern (decor).

Decorative laminates are much used in the building and furniture industry. Such products have a cladding of highly abrasion resistant cured resin, which furthermore has high resistance against chemicals and moisture. Generally, these products comprise cured resin and fibrous material. Generally the laminates are made from decorative paper, impregnated with melamine-formaldehyde resin, which are cured by heat and pressure on one or more base sheets. For example, particle or card board can be covered with one or more melamine-formaldehyde resin impregnated paper sheets, which are subsequently cured by heat and pressure. In another example, melamine-formaldehyde resin impregnated papers are put on top of a stack of phenol-formaldehyde resin impregnated kraft papers and subsequently cured. Melamine-formaldehyde resins are well known, and for example described in EP-A 0561432 and U.S. Pat. No. 4,424,261.

Three often used methods for making final laminates are known: Low Pressure Laminate (LPL), High Pressure Laminate (HPL) and Continuous Pressure Laminate (CPL). Low pressure is most often used with card-board or particle board, whereas high pressure generally is used with the so-called kraft papers. The sheets or products resulting from the HPL-process are generally not self-supportive. In general, they are bonded, with a suitable adhesive or glue, to a rigid substrate such as particle board or medium density fiber board (MDF). In a continuous pressure laminate process, papers are fed from a role into a continuous belt press.

Current production suffers from drawbacks which are not easily overcome. One problem is that the laminates made in the high pressures or continuous process are so hard, that it is difficult to bend or ‘post-form’ these sheets. At present, post-forming characteristics are often achieved by either incorporating expensive modifiers like benzoguanamine or acetoguanamine (as described in EP-A 0561432), or by making melamine-formaldehyde resins at elevated pressure, allowing more melamine to react with formaldehyde. The latter process is relatively expensive, and requires pressure vessels. Yet, it would be an advantage if—while keeping the abrasion resistance and chemical resistance properties—the HPL or CPL sheets would be bendable, so they could be made to cover e.g. MDF boards not only on one side, but in one process step, also one or more of the other sides in a cost effective and efficient manner. Another drawback is the use of formaldehyde, which is known to be a toxic chemical. The resin used to impregnate paper is basically a formaldehyde-melamine resin. After cure, the laminate still releases some formaldehyde, which may cause environmental concerns. For LPL sheets, it would furthermore be an advantage, if it would be possible to make laminates with less melamine, or to preclude the necessity to make MF resins.

One object of the invention is a paper, impregnated with resin, suitable for laminates with low formaldehyde emission and/or improved post forming characteristics without the need of applying pressure during resin production, or expensive modifiers.

Another object is to provide resin impregnated paper with higher amounts of melamine per meter square than nowadays achievable in normal processing.

Another object of the invention is a process for making a laminate with improved low formaldehyde emission and/or post-forming characteristics in an economical attractive way.

These objects and other advantageous features are achieved with the present invention, wherein a paper substrate is first impregnated with an amine-resin and thereafter subjected to vapor deposition of triazine. The invention thus relates to a resin impregnated paper substrate comprising crystalline triazine.

The majority of laminates is made with paper. Some laminates are made from non-woven fibrous material with paper-like characteristics, like non-woven glass fibers, carbon fibers, natural fiber or polymeric fiber cloth or blends of these materials. In the present invention, the word paper is used to comprise other non-woven materials, unless specifically defined.

In one embodiment, it is preferred to use paper, consisting of non-woven and non-spun cellulose fiber.

In one embodiment, the paper is a decorative paper. The decoration preferably is a printed décor, and may be representing a wood structure. In another embodiment, the décor paper is a plain color, like white. In another embodiment, the decor represents granite, marble or other naturally occurring materials. The printing ink may be for example an alkyd based ink, or a polyester acrylate based ink.

In another embodiment, the paper is suitable as so-called overlay paper. Overlay papers are highly transparent when impregnated and cured, and are used as scratch resistant top layer applied on top of a decorative paper. Often, overlay papers are used in laminate manufacturing for wood panels for flooring.

The printed paper preferably has a weight of about 15 g/m² or more, preferably of about 70 g/m² or more. Generally, the paper will have a weight of about 200 g/m² or less, preferably of about 150 g/m² or less. Such paper types do provide an optimum appearance of the resultant decorative panel, but also a good penetration power of the resin. The overlay paper generally has a weight of about 10 g/m² or more, preferably about 15 g/m² or more, and generally a weight of about 60 g/m² or less, preferably about 40 g/m² or less.

In one embodiment, the paper is a continuous role of paper. Such role of paper generally will be several hundred meters, for example 200 m long or more, preferably 500 m or more. Generally, the length will be about 10 km or less, or about 5 km or less. Generally, the paper will have a width of 50 cm or more, preferably 1 m or more. Generally, the width will be about 6 m or less, or 3 m or less. In another embodiment, the paper may be leaves.

Generally, amine resins are amine-formaldehyde resins. Suitable examples of resins that are used to impregnate papers for laminates include, but are not limited to urea-formaldehyde (UF) resins and melamine-formaldehyde (MF) and phenol-formaldehyde resins (PF).

The MF resins generally have a ratio of formaldehyde to melamine (F/M ratio) of about 1.7 to about 1.55. These ratios are achieved at ambient pressure synthesis at 55-65% solids, which is commonly used in industry. At a lower F/M ratio (formaldehyde to melamine ratio) melamine does not any more dissolve (at normal pressure). Resins with higher F/M ratio's, for example 2 or 2.5, are useful as well, but the resultant laminates are relatively brittle, and emit higher concentrations of formaldehyde and therefore are not commonly used. If it were possible to use these higher ratio's F/M resins, one could improve the economics of the processes, because resin preparation would be shortened because the melamine dissolves faster.

The UF resins are cheaper, but have relatively bad water-resistant properties. Hence, UF resin are commonly used in the interior of laminates. The exterior, or outer layer should be largely melamine based resin. The present inventions allows to impregnate paper with UF or melamine modified UF resin (MUF-resin). Such MUF resin may be an UF resin modified with about 1 wt % of melamine or more, preferably about 5 wt % melamine or more. Such MUF will have an amount of melamine of about 50 wt % or less, for example 30 wt % or less. When such UF or MUF impregnated paper has thereon melamine vapor deposited, the subsequent cure yields a melamine rich top layer having MF like characteristics. In this way, it is possible to use less MF resin (thinner layer), or no MF resin, by virtue of which the synthesis of MF resin is not necessary any more.

In another embodiment, the interior papers are impregnated with phenol-formaldehyde resins. At present, these resins have a strong brown color, and are therefore—in general—not suitable for top paper-laminate. Otherwise, also the outer paper could be—in part—be a phenol-formaldehyde resin.

In one embodiment of the invention, the MF resin used to impregnate the paper has a F/M ratio of about 1.5 or higher, and preferably a F/M ratio of about 1.5 to about 1.7. In a further embodiment, the paper is first impregnated with UF (urea-formaldehyde) resin, and dried, and thereafter impregnated with MF resin. In another embodiment, the paper may be impregnated with a melamine/formaldehyde resin with a F/M ratio of about 1.7 to about 2.5. This has the advantage to speed up the resin manufacture.

The amine resin like urea-formaldehyde or melamine-formaldehyde resin can be made as known by the skilled person. Generally, melamine or urea or another azine is added to a formaldehyde solution. Generally, the amount of formaldehyde is about 30 wt % or more in water. The amount of formaldehyde generally is about 40 wt % or less. The amount of amine like melamine or urea generally is about 30 wt % or more. Generally, the amount is about 50 wt % or less. Generally, a catalyst is present during the preparation of the resin. Suitable catalysts are organic or inorganic bases. Suitable bases include sodium hydroxide or potassium carbonate. It is further possible, to have plasticizers, extenders, flow promoters present or co-react with the melamine-formaldehyde resin. Suitable examples include, but are not limited to caprolactone, caprolactam, mono-, di- or tri-ethylene glycol, mono, di or poly alcohols like butanediol, sorbitol, glucose, glycol-ethers like trioxytol, urea and thiourea. Further, part of the melamine can be replaced by urea, to make a melamine-urea-formaldehyde resin (MUF). The term melamine-formaldehyde resin as used in this application comprises these variants. Urea modified MF resin will be considered MF if less than about 40 wt % of the melamine is replaced by urea, preferably, less than about 30 wt % is replaced, more preferably, less than about 20 wt %. Resins with optimal characteristics are obtained if one uses about 10 wt % of urea or less. The cure time of the resin can be adjusted with a catalyst.

The impregnated paper is subsequently dried as is common in the art. Drying can be achieved by heating the impregnated paper in an oven at about 50° C., preferably about 80° C. or more. Generally, the temperature will be about 140° C. or less, preferably 120° C. or less. Thereafter, the impregnated paper is subjected to vapor deposition of a triazine. The vapor deposition will yield crystalline triazine. Crystalline is here used in the sense that with scanning electron microscopy it is possible to see triazine crystals at a magnification of ten to the sixth. (1 cm is 10 nm)

The amount of crystalline triazine on the paper is generally about 5 g/m² or more, and preferably about 10 g/m² or more. An even smaller amount of triazine still may be advantageous, but its added value is lower. Suitable examples of lower amounts include about 1, 2 or 3 g/m². The amount of triazine on the paper is generally about 100 g/m² or less, preferably about 90 g/m² or less. Higher amounts may cause difficulties with processing the triazine comprising impregnated paper. It may become more difficult to dissolve all triazine in the curing step, assuming that is a requirement.

Suitable triazines for vapor deposition include, but are not limited to, melamine, melam, acetoguanamine, benzoguanamine, dicyanediamine, toluenesulphonamide, thiourea and urea. Preferred examples are melamine and urea, because of cost reasons.

In one embodiment, it is preferred to use melamine as the triazine compound for vapor deposition, as that is a widely available material and gives very good characteristics. In practice, it appears difficult to make resins with melam, so use of these materials in laminates has been very limited. It now becomes easily possible to make laminates which comprise melam in the ultimate cured resin.

In another embodiment of the invention, it is preferred to use thiourea as the triazine for vapor deposition. Thiourea is sometimes used to improve the gloss of laminates. With the present invention it is possible to deposit relatively low amounts of thiourea on top of a azine-resin impregnated paper, and thereby it is possible to achieve a gloss improvement.

In one embodiment of the invention, a mixture of triazines is used for vapor deposition. In another embodiment of the invention, two or more triazines are vapor deposited consecutively, from different vapor deposition vessels. This may be advantageous over the use of mixtures, as far as the sublimation temperature varies for the different triazines.

In another embodiment, both sides of the impregnated paper are subjected to vapor deposition of a triazine.

The vapor deposition of triazine on the paper substrate can be performed as described in U.S. Pat. No. 6,632,519, WO 2004/101662 and WO 2004/101843, which disclosures are herewith incorporated by reference. The vapor deposition preferably is carried out in a vacuum chamber, at reduced pressure. Preferably, the deposition is performed in an inert atmosphere, like for example a nitrogen atmosphere.

Preferably, the vapor deposition process takes place in a chamber having about ambient pressure or less, preferably of about 100 mbar or less, preferably of about 10 mbar or less. The resin impregnated paper—when ready for pressure cure—generally contains some water (5-10%). It is preferred that sufficient water remains in the resin after vapor deposition. Hence, the resin impregnated paper preferably is subjected to reduced pressure for only a short period of time, and preferably not to a high vacuum. In one embodiment, a high vacuum is preferred, as smaller crystals are formed, which dissolve faster. In another embodiment, a lower vacuum is preferably applied. A lower vacuum can be more easily obtained. Also, such lower vacuum allows a longer residence time of an impregnated paper without drying the resin to an extent that it does not flow anymore. Generally, the resin impregnated paper will be subjected to vapor deposition at a pressure of about 10⁻⁵ mbar or more for a high vacuum. The high vacuum generally will be at a pressure of about 10⁻³ or less. It is also possible for example to perform the vacuum deposition at about 0.1 mbar or more, in which case one would obtain somewhat larger crystals. The pressure to chose will depend on the drying effect of the vapor deposition, and the type of resin. For example, resins for HPL are non- or slightly catalyzed, and it is just necessary to keep sufficient water in the resin to allow sufficient flow of the resin. On the other hand, generally, resins for LPL contain more catalyst. In this case, one has to pay attention to through cure in during vapor deposition, as well as physical drying. When finding optimal pressing conditions for flow, cure and triazine dissolution, the man skilled in the art will know e.g. to adjust the catalyst loading as to influence the B-time. Another important parameter is the amount of physically water present in the resin. If necessary, it is possible to spray additional water in case the resin does not have sufficient water present to flow well during the press cycle.

In general, the triazine will be heated. The required temperature for sublimation is dependent on the vacuum, and is preferably about 250° C. or higher, preferably about 300° C. or higher, even more preferred about 310° C. or higher. Generally, the temperature to heat the triazine will be close to the decomposition temperature, which is different for each triazine. For melamine, the temperature will be about 350° C. or lower. For melam, the temperature will be about 450° C. or lower. Generally, to achieve a reliable vapor deposition of the triazine, it is preferred to keep the substrate at a temperature that is about 100° C. or more lower than the temperature for heating the triazine, preferably, the temperature difference is about 200° C. or more, and even more preferred, about 300° C. or more. Preferably, the substrate is kept at about room temperature, e.g. at a temperature of about 20° C. Some heating will occur during the deposition step, but this is not critical. The amount of triazine deposited can be steered by the amount of time the paper is subjected to the vapor deposition, the concentration of the triazine in the vapor (which is dependent a.o. on the temperature the triazine is heated and the pressure).

In one embodiment of the present invention, the speed of the paper over the vacuum chamber is about 20 m/min or more, preferably about 30 m/min or more. Generally, the speed will be about 100 m/min or less, for example speeds of 40, 50 or 60 m/min are preferably applied. The temperature of the triazine in the vacuum chamber has a temperature of about 300° C. or higher, preferably about 310° C. or higher. The vacuum is preferably about 10⁻⁵ mbar or more, and about 1 mbar or less.

The triazine on the impregnated paper substrate preferably will have a microcrystalline structure. On a SEM photograph, a man skilled in the art is able to determine the crystal size of melamine. The melamine crystals preferably show as multi crystalline platelets with a width of about 100 μm or less, preferably about 50 μm or less. Generally, the width of the crystals will be about 20 nm or more, preferably about 50 nm or more. The thickness of the platelets generally will be about 10 μm or less, for example about 3 μm or less. Generally, the thickness will be about 2 nm or more, preferably about 5 nm or more.

Preferably, the amount of resin on the paper (counted as triazine as vapor deposit and the resin combined) is about 30 wt % or higher, preferably about 35 wt % or higher. Generally, the amount will be about 95 wt % or lower, or for example 90 wt % or lower. These weight percentages are calculated relative to the total weight of the paper plus triazine plus resin. Depending on the use, loadings can be different. For example, conventional overlay paper will preferably have a resin content of about 65 to 80 wt %. For example, conventional solid color paper may have a resin loading of about 45 to 55 wt %, and conventional printed paper can have a resin loading of about 35 to 45 wt %. The volatile content of the impregnated paper preferably is about 5-10 wt %.

With the products and process of the present invention, it is possible to obtain a higher amount of triazine per square meter than commonly obtained, in a very efficient way. With normal resin preparation and impregnation, it generally is possible to have paper with about 30 g/m² melamine on a light paper. With the current process, it is possible to arrive at substantial higher amounts of triazine like melamine per square meter, such as for example about 40 g/m² or more on a paper of 30 g/m². These papers if used for decorative laminates have better flow characteristics, and better post-forming characteristics. In case the high amount of triazine is combined with an F/M ratio of about 1.6 or lower, its formaldehyde emission characteristics are improved as well.

In one embodiment of the invention, the present invention provides for a B-stage melamine and MF resin comprising paper, in which the amount of melamine is about 0.8 g/m² per g/m² of paper, or more, preferably about 0.85 g/m² or more, and even more preferred, about 0.9 g/m² of melamine or more per g/m² of paper. Generally, the amount of melamine will be about 2 g/m² or less per g/m² of paper, for example about 1.2 g/m² or less. B-stage is generally used to mean an MF resin that has reacted to such an extent that a dry (to the hand) impregnated paper is obtained. Generally, this means that formaldehyde and melamine are reacted to at about 1:1. In conventional impregnated paper, this is about 5-10% reaction. The paper comprises generally about 5-15% water, to obtain a dried impregnated paper, which still shows flexibility.

In another preferred embodiment of the invention, the paper is impregnated with an UF or MUF resin, and subjected on at least one side with an amount of vapor deposited melamine of about 15 g/m² or more. Such paper can be used in a pressure laminate process to achieve a top-layer of cured melamine-resin with good surface properties, without the need of making MF resin. Particularly good results are obtained with paper, impregnated with an UF resin and an vapor deposited with an amount of melamine of about 20 or 30 g/m² or more.

The resin impregnated and crystalline triazine comprising paper is according to the present invention used to make laminates by subjecting said paper to increased temperature and pressure whereby at least part of the crystalline triazine is dissolved and simultaneously cured with the resin. Said paper is generally used with one or more other layers, as described below.

In one embodiment, it will be important to have most or all crystalline triazine dissolved during the curing (press) step in order to obtain a clear resin. In order to have all triazine dissolved at a reasonable speed, it is preferred to have a calculated F/M ratio of about 1.1 or higher; with somewhat longer press cycles, a ratio of about 1 may be effective. It is possible to influence the gelling time by adjusting the amount of catalyst. In case of melam, one mole of melam equalizes 1.33 mole of melamine in the theoretical F/M calculation. In this specification, F/M ratio is used, wherein the melamine can be in part, or completely be exchanged with another triazine. If one calculates the amount of melamine on paper, melam counts for 1.66 melamine, whereas urea or acetoguanamine counts for about 0.66 melamine.

In another embodiment, the amount of melamine, and the curing process are chosen such that part of the melamine stays as solid. This is in particular useful in case white laminates are made, as in this way the color strength of white is improved.

In one embodiment of the invention, the other layers comprise kraft papers, impregnated with phenol-formaldehyde resin, and subjecting the stack to a pressure of about 30 N/m² or more, preferably 100 N/m² or more. Generally, the pressure will be about 150 N/m² or less. The temperature preferably in this HPL process is about 130° C. or more. Preferably, the temperature is about 220° C. or less, and in other embodiment 150° C. or less. Generally, the time used for curing will be generally about 2 to about 60 min.

In another embodiment, the other layer is a particle board, medium density fiber board, card board, and subjecting the stack to a pressure of about 20 N/m² or less. Generally, in this case of LPL, the temperature will be about 170° C. or higher. Generally, the temperature will be about 220° C. or lower. Generally, the time used for curing will be about 5 sec or more, for example 10 sec or more. The time for curing generally will be about 120 sec or less, preferably about 60 sec or less, and most preferred about 20 sec or less.

In one embodiment, the other layer comprises an overlay paper. In a further embodiment, the overlay paper contains hard abrasive mineral particles because with these, scratch and abrasion resistance can be improved. Generally, particles will have a size of about 50 nanometer or more, preferably about 30 micrometer or more. Generally, the size of the particles will be 200 micrometer or less, preferably about 150 micrometer or less. Particle with a size of 50 nanometer to 30 micrometer are for example suitable to improve scratch resistance. Particles with a size of 30 to 150 micrometer are for example suitable to improve abrasion resistance. Suitable examples of mineral particles include, but are not limited to silicon dioxide (silica), silicon carbide and aluminum oxide (corundum), of which aluminum oxide is preferred. The mineral particles may be present in the resin for impregnating the overlay paper. The particles may also be coated on the surface of the overlay paper after impregnating said paper. It is also possible to deposit the abrasive particles on the decorative paper, preferably after impregnating. In this embodiment, an overlay paper may not be necessary to achieve outstanding wear properties.

In one embodiment of the present invention, the triazine is deposited after depositing the abrasive particle. This has as an advantage that the life time of the chromium platen used in the press is increased, because the abrasive particle are covered with melamine.

The above-described processes for making laminates are preferably used in a high pressure process (HPL) and/or continuous process (CPL). A CPL process can be performed continuous by what is known as “role-to-role” process: when one role of paper is near its end, a new role will enter in the processing machine, thereby making this process virtually completely continuous.

The present invention therefore also relates to an apparatus for the continuous production of pressure laminates comprising
1) a holder for a role of paper,
2) a bath for resin impregnation
3) a dryer for drying the impregnated paper
4) a triazine vapor depositing chamber
5) a press operable at elevated temperature sufficient to heat and cure the resin and at least part of the vapor deposited triazine.

The triazine depositing chamber preferably is a closed chamber with two slits in the side walls, allowing the paper to enter and exit. The slits are sufficiently small to keep the vapor triazine substantially in the chamber, and to allow slight or stronger decreased pressure. Suitable pressure includes pressures of about 1-100 10⁻⁵ mbar, or of about 0.01 to 1 mbar

Preferred laminates have lower formaldehyde emission than conventional commercial laminates. Formaldehyde emission can be measured according EN 120 and according EN 717-1, -2, and -3.

The resultant laminates have good post-forming characteristics. This is in particular important for HPL, because these have to be attached to a substrate, and it is preferred, that the laminate can be bent if desired. However, post-forming characteristics are also useful with LPL, as it improves handling characteristics of the product, like with drilling, sawing and the like. Post-forming characteristics can be measured according EN 438/2.1

The invention will be further elucidated by the following examples, without being limited thereto.

### Resin Preparation

A melamine resin was made with an F/M ratio of 1.5 by reacting 956 g melamine with 924 g (37%) formalin and 78 g di-ethylene glycol, having added 542 g of water and sufficient 10% NaOH to achieve a pH of 9.3, at elevated temperature (about 100° C.). When the cloud point was reached, the water tolerance (WT) was tested. When the WT was 260%, the reaction mixture was quickly cooled to room temperature, and the pH was again adjusted to 9.3. To 990 g of this resin, 2 g wetting agent (Würtz 9594) and 2 g release agent (Würtz 2523W) was added. The pH now was 8.9, and the B-time was 304 sec. The resin was used as such. In case the B-time would have been larger, an amount of p-toluenesulphonic acid would have been added to arrive at a B-time of about 300 sec.

### Paper Impregnation

Blue paper (110 g/m²) and wood print paper (70 g/m²) were used for impregnation. Papers were impregnated with 110% of a resin and dried in a Fresenberger oven at 100° C. for 9 min to achieve a resin with about 6% water.

### EXAMPLES 1-5

### Vapor Deposition of Melamine on MF Impregnated Paper

Blue or wood-print paper which were impregnated with melamine resin as described were used for vapor deposition of melamine. In order to assess the amount of melamine deposited, analysis stripes of paper were dried and used in parallel to the actual paper. In order to deposit melamine, the paper was put in the vacuum chamber, the melamine heated to 305° C. while the pressure was reduced to about 2-9 10⁻⁵ mar for examples 1, 2 4 and 5. The pressure was 0.1-0.2 mbar in case of example 3. During a certain time, melamine was deposited, as shown in table 1.

TABLE 1

| | | | Total | Amount |
|---|---|---|---|---|
| Example | Time side 1 | Time side 2 | melamine | per m² |
| 1 (blue paper) | 6 min | — | 1.6 g | 25 |
| 2 (blue paper) | 2 min | — | 0.85 | 13.5 |
| 3 (blue paper) | 3 min | 3 min | 0.35 | 5.6 |
| 4 (blue paper) | 2 min 10 sec | 2 min 10 sec | 0.65 | 10.3 |
| 5 (wood print) | 2 min 20 sec | 2 min 20 sec | 0.75 | 11.9 |

The amount of melamine deposited per time period was negatively influenced by fouling of the oven and chamber. Therefore, the time necessary to achieve the required melamine deposition was increased from example 3 onwards. However, the examples show that melamine was successfully vapor deposited on resin impregnated paper; both on one side and on two sides, in amounts substantially larger than generally used in the process according to U.S. Pat. No. 6,632,519. It should also be noted, that these experiments are performed on laboratory equipment. On industrial scale, one can easily obtain high speeds (several seconds or less per meter) vapor deposition that would yield amounts as shown in this table.

### EXAMPLES 6-7 AND COMPARISON EXPERIMENTS 1-2

### Laminate Formation

Laminates were made by stacking one of the layers 2 or 5 on phenol-formaldehyde papers, suitable for post-forming. Laminates of example 6 and comparative experiment 1 were pressed as described in EN 438 at a pressure of 8 MPa (=8 MN/m²). Laminates of example 7 and comparative experiment 2 were pressed as in short cycle conditions (20 seconds at 170° C.). Post forming characteristics are measured as described in EN 438/2.1, requiring bending over a radius of 10 times the thickness of the laminate. The results are pass, when no cracks are observed, or fail, if the top layer shows defects

Results are shown in table 2

TABLE 2

| Example | Melamine | F/M ratio | Post-forming test |
|---|---|---|---|
| 6 (with paper 2) | 90.0 g/m² | 1.28 | Pass |
| 7 (with paper 5) | 89.0 g/m² | 1.3 | Pass |
| Comparative | 78.5 g/m² | 1.5 | Fail |
| experiment 1 with | | | |
| non-treated blue | | | |
| paper | | | |
| Comparative | 50.0 g/m² | 1.5 | Fail |
| experiment 2 with | | | |
| non-treated wood- | | | |
| print paper | | | |

These results show that at least part of the melamine did dissolve in the resin during cure, and that improved post-forming characteristics were obtained without the need of a special resin. Example 7 showed an improved gloss with respect to the laminate of comparative experiment 2.

1. Resin impregnated paper substrate with comprises crystalline triazine.

2. Resin impregnated paper substrate according claim 1, wherein the crystalline triazine is vapor deposited triazine.

3. Resin impregnated paper substrate according to claim 1, wherein the amount of triazine is about 5 g/m² or higher.

4. Resin impregnated paper substrate according to claim 1, wherein the amount of triazine is about 100 g/m² or lower.

5. Resin impregnated paper substrate according to claim 1, wherein the triazine is melamine.

6. Resin impregnated paper substrate according to claim 1, wherein the resin is a ME resin.

7. Resin impregnated paper substrate according claim 1, to wherein the resin is an UF or MUF resin.

8. Resin impregnated paper according to claim 1, wherein the
paper consists of non-woven and non-spun cellulose fiber.

9. Resin impregnated paper according to claim 1, wherein the paper has a weight of about 15 g/m² or more, and of about 200 g/m² or less.

10. Resin impregnated paper according to claim 1, wherein the paper is a decorative paper.

11. Resin impregnated paper according to claim 10, wherein the paper is unicolored.

12. Resin impregnated paper according to claim 10, wherein the paper has a print mimicking naturally occurring material.

13. Resin impregnated paper according to claim 1, wherein the paper is an overlay paper.

14. Resin impregnated paper according to claim 1, wherein the triazine is microcrystalline, having a platelet structure with a size of about 100 pm or less.

15. Process for making a paper according to claim 1, wherein paper is subjected to resin impregnation, drying and thereafter vapor deposition in a vacuum chamber, the speed of the paper over the vacuum chamber is about 0.1 m/s or more, and about 10 m/s or less, the triazine in the vacuum chamber has a temperature of about 250° C. or higher, preferably about 330° C. or higher, and the vacuum is about 100 mbar or more, and whereby the temperature of the paper substrate is 250° C. less than the heating temperature of the triazine.

16. Process for making a laminate comprising at least one cured layer of amine formaldehyde resin and a paper, wherein a resin impregnated paper according to claim 1, is submitted with one or more other layers to pressure and/or sufficient temperature to cure the resin and at least part of the crystalline triazine.

17. Process according to claim 16, wherein the resin and triazine have a theoretical F/M ratio of 1.5 or higher.

18. Process according to claim 16, wherein the resin and triazine have a theoretical E/M ratio of 1.5 or lower.

19. Process according to claim 16, wherein the process is a continuous role-to-role process.

20. B-stage triazine and azine-resin comprising paper, in which the amount triazine, calculated as melamine is about 0.8 g/m² or more per g/m² of paper.

21. Paper according to claim 20, wherein the amount of triazine calculated as melamine is about 0.9 glm² or more per glm² of paper.

22. Paper according to claim 19, wherein the triazine is melamine.

23. Paper according to claim 19, wherein the amine resin is a ME resin.

24. Paper according to claim 19, wherein the amine resin is an UF resin.

25. Use of a paper according to claim 1, in a continuous pressure laminate process.

26. Apparatus for the continuous production of pressure laminates comprising
1) a holder for a role of paper,
2) a bath for resin impregnation
3) a dryer for drying the impregnated paper
4) a triazine vapor depositing chamber
5) a press operable at elevated temperature sufficient to heat and cure the resin and at least part of the vapor deposited triazine.

27. Apparatus of claim 26 wherein the triazine depositing chamber is a closed chamber with two slits in the side walls, allowing the paper to enter and exit, which slits are sufficiently small to keep the vapor triazine substantially in the chamber and to allow a decreased pressure.
